(19) United States
(12) Patent Application Publication
(10) Pub. No.: US 2003/0080348 A1
(43) Pub. Date: May 1, 2003

(54) Heterojunction field-effect transistor

(75) Inventors: Makoto Inai, Nagaokakyo-shi (JP); Hidehiko Sasaki, Nagaokakyo-shi (JP)

Correspondence Address: OSTROLENK FABER GERB & SOFFEN, 1180 AVENUE OF THE AMERICAS, NEW YORK, NY, 100368403

(73) Assignee: Murata Manufacturing Co., Ltd.

(21) Appl. No.: 10/277,656

(22) Filed: Oct. 21, 2002

(30) Foreign Application Priority Data
Oct. 25, 2001 (JP) 2001-327870

(51) Int. Cl. H01L 31/0328

(52) U.S. Cl. 257/192

(57) ABSTRACT

A heterojunction field-effect transistor having a high breakdown voltage and a low series resistance during operation suitable for use in microwave and millimeter-wave band oscillators and power amplifiers is provided. The heterojunction field-effect transistor has a gate recess structure and includes a gate electrode, a barrier layer, a contact layer, and a recess layer formed between the barrier layer and the contact layer. The recess layer is constituted from a plurality of recess sublayers, and the carrier density of the lowermost sublayer of the recess sublayers is ⅓ to 3 times the carrier density of the other recess sublayers.

### BACKGROUND OF THE INVENTION

1. Field of the Invention

The present invention relates to heterojunction semiconductor devices. In particular, the present invention is directed to a heterojunction field-effect transistor operable in the microwave and millimeter-wave bands.

2. Description of the Related Art

Heterojunction field-effect transistors such as high electron mobility transistors and doped channel heterojunction field-effect transistors have been known as elements that can operate in the microwave and millimeter-wave bands. FIG. 4 is a cross-sectional view of a high electron mobility transistor (HEMT).

As shown in FIG. 4, the HEMT is constituted from a semi-insulating substrate 84, which is the bottom layer, a buffer layer 85, a channel layer 86, a first barrier layer 87, a second barrier layer 88, a recess layer 89, a contact layer 90, a gate electrode 81, a source electrode 82, and a drain electrode 83, respectively in that order.

The source electrode 82 and the drain electrode 83 are disposed on the top face of the contact layer 90. The contact layer 90 is a heavily doped n-type GaAs layer. The source electrode 82 and the drain electrode 83 make an ohmic contact with the contact layer 90.

The contact layer 90 is selectively etched to form a recess therein. The gate electrode 81 is then formed in the recess and on the recess layer 89. The gate electrode 81 and the region inside and near the recess are covered with a protective film 91.

The region between the gate electrode 81 and the source electrode 82 and between the gate electrode 81 and the drain electrode 83 largely affects the breakdown voltage of the heterojunction field-effect transistor and is hereinafter referred to as the “recess region”. In FIG. 4, the recess region is indicated by dotted lines. As shown in FIG. 4, the recess region has a depth from the top edge of the recess to the bottom edge of the gate electrode 81 and a length from one top edge to the opposing top edge of the recess, excluding the section where the gate electrode 81 is formed. The recess region is constituted from a first recess region 92, which is part of the recess layer 89, and a second recess region 93, which is part of the contact layer 90.

A high electron mobility transistor (HEMT) may have a single-step recess structure, as shown in FIG. 4, or a two-step recess structure, as shown in FIG. 5. FIG. 5 is a cross-sectional view of an example of a HEMT having a two-step recess structure.

As shown in FIG. 5, the HEMT includes a semi-insulating substrate 104 at the bottom, a buffer layer 105, a channel layer 106, a first barrier layer 107, a second barrier layer 108, a recess layer 109, a contact layer 110, a gate electrode 101, a source electrode 102, and a drain electrode 103, respectively in that order.

The source electrode 102 and the drain electrode 103 are formed on the upper face of the contact layer 110. The contact layer 110 is a heavily doped n-type GaAs layer, and the source electrode 102 and the drain electrode 103 thus make an ohmic contact with the contact layer 110.

The contact layer 110 is selectively etched to form a large recess, and the exposed part of the recess layer 109 is then selectively etched to form a small recess, thereby providing a two-step recess. The gate electrode 101 is formed on the second barrier layer 108 inside the recess. The gate electrode 101 and inside and around the recess are covered with a protective film 111.

The region exposing the recess layer 109 between the gate electrode 101 and the source electrode 102 and between the gate electrode 101 and the drain electrode 103 largely affects the breakdown voltage of the heterojunction FET and is referred to as the “recess region”. In FIG. 5, the recess region is indicated by the dotted lines. As shown in FIG. 5, the recess region has a depth from the bottom face of the contact layer 110 to the bottom of the gate electrode 101 and a length from one edge of the contact layer 110 to the opposing edge of the contact layer 110, excluding the section where the gate electrode 101 is formed. The recess region includes a first recess region 112, which is part of the second barrier layer 108 and a second recess region 113, which is part of the recess layer 109.

The first recess region 112 is composed of undoped AlGaAs as in the second barrier layer 108, thereby achieving a high breakdown voltage. The second recess region 113 is composed of heavily doped n-type GaAs as in the recess layer 109, thereby preventing depletion.

This two-step recess structure generally increases the breakdown voltage at a low electric field. In the two-step recess structure, each of the path between the gate electrode 101 and the source electrode 102 and the path between the gate electrode 101 and the drain electrode 103 has a two-step structure. Thus, the applied. electric field has a stepped characteristic, and a smaller electric field is applied to each of the steps than that in the single recess structure, thereby increasing the breakdown voltage.

However, the heterojunction FET having a single-step structure shown in FIG. 4 has the second recess region 93 formed in the heavily doped contact layer 90. As a result, the carrier density of the second recess region 93 becomes at least approximately 5 times higher than the carrier density of the first recess layer 92, readily causing collision ionization at a low electric field. When an electric field is applied between the gate electrode 81 and the source electrode 82 or between the gate electrode 81 and the drain electrode 83, the electric field concentrates in the second recess region 93 where the carrier density is high and collision ionization readily occurs. This causes breakdown between the source and the gate or between the gate and the drain at a low electric field, which is a problem.

As for the heterojunction FET having the two-step recess structure shown in FIG. 5, the difference in carrier density between the first recess region 112 and the second recess region 113 is large. Thus, when an electric field is applied between the gate electrode 101 and the source electrode 102 (or drain electrode 103), the electric field concentrates in the heavily doped recess region 113, resulting in breakdown at a low electric field. Moreover, because the first recess region 112 is in an undoped AlGaAs layer having an extremely low carrier density, an increase in the series resistance occurs during the operation of the heterojunction FET, which is a problem.

Whereas oscillators and power amplifiers operable in microwave and millimeter-wave zones require high gain, high output, and high efficiency, a high series resistance and a low breakdown voltage of heterojunction HEMTs have been the major factors that degraded the characteristics of these devices.

### SUMMARY OF THE INVENTION

In order to overcome the problems described above, preferred embodiments of the present invention to provide a heterojunction field-effect transistor (FET) exhibiting a high breakdown voltage and a low series resistance during operation. To achieve this object, a recess region of the heterojunction FET which affects the breakdown voltage is constituted from a plurality of sublayers, the carrier densities of which are within a predetermined range.

According to a preferred embodiment of the present invention, the present invention provides a heterojunction field-effect transistor having a gate recess structure, the heterojunction field-effect transistor including a gate electrode, a barrier layer, a contact layer, and a recess layer formed between the barrier layer and the contact layer, the recess layer comprising a plurality of recess sublayers. The bottom of the gate electrode is embedded in the lowermost sublayer of the plurality of recess sublayers, and the carrier density of the lowermost sublayer is ⅓ to 3 times the carrier density of the other recess sublayers.

This structure reduced the concentration of the electric field in the recess region and thus prevents breakdown due to an applied electric field. A heterojunction FET having a high breakdown voltage can be obtained.

Preferably, each of the recess sublayers has a carrier density in the range of 7×10⁺¹⁷ to 5×10⁺¹⁸ cm⁻³ so as to prevent an expansion of the surface depletion layer and an increase in the resistance in the recess region. Thus, a heterojunction FET having a low series resistance can be provided.

Preferably, the recess region has a multi-step structure, and the lowermost layer of the recess sublayers is an AlGaAs layer having a large bandgap since this structure further increases the breakdown voltage. Preferably, the FET has a doped channel structure so as to inhibit the carrier transition from the recess layer to the channel layer and to further reduced the series resistance. Moreover, because a heterojunction FET having a high breakdown voltage and a low series resistance during operation can be obtained, oscillators and power amplifiers operable in the microwave and millimeter-wave bands using such FETs can achieve high gain, high output, high efficiency, and high reliability.

Other feature, elements, characteristics and advantages of the present invention will become more apparent from the following detailed description of preferred embodiments of the present invention with reference to the attached drawings.

### BRIEF DESCRIPTION OF THE DRAWINGS

FIG. 1 is a cross-sectional view of a heterojunction FET according to a first embodiment of the present invention;

FIG. 2 is a graph showing the relationship between the density ratio of the recess sublayers and the breakdown voltage;

FIG. 3 is a cross-sectional view of a heterojunction FET according to a second embodiment of the present invention;

FIG. 4 is a cross-sectional view of a conventional heterojunction FET having a single-step recess structure; and

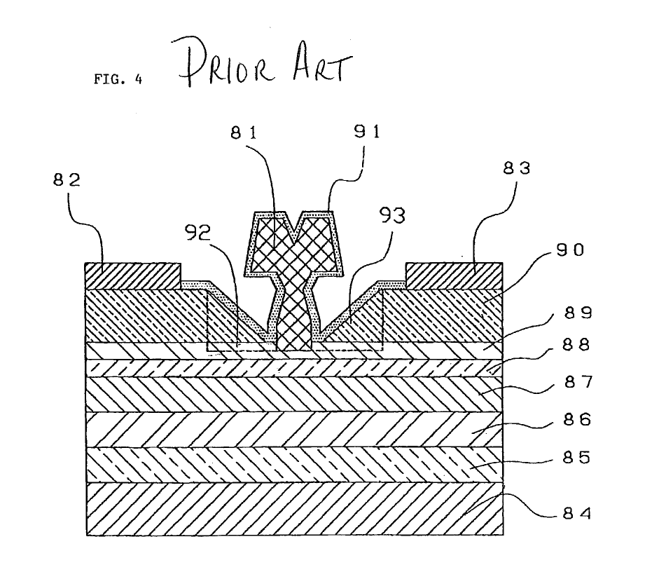

FIG. 5 is a cross-sectional view of a conventional heterojunction FET having a two-step recess structure.

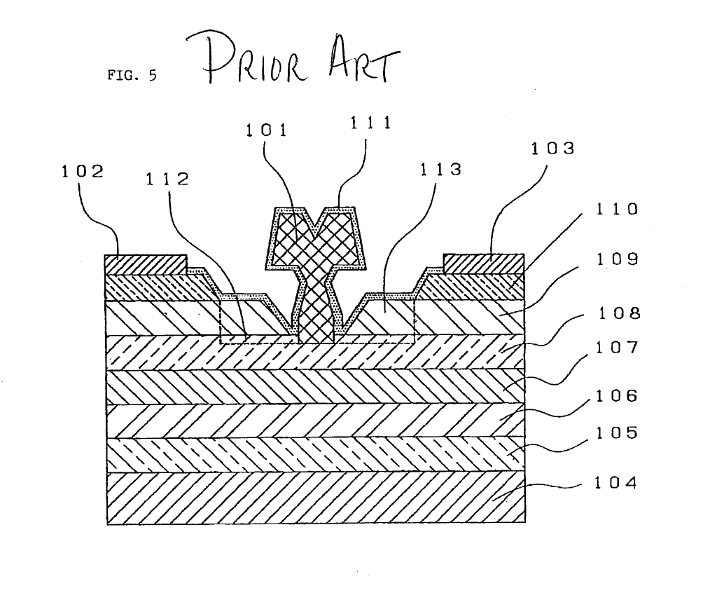

### DESCRIPTION OF THE PREFERRED EMBODIMENTS

First Embodiment

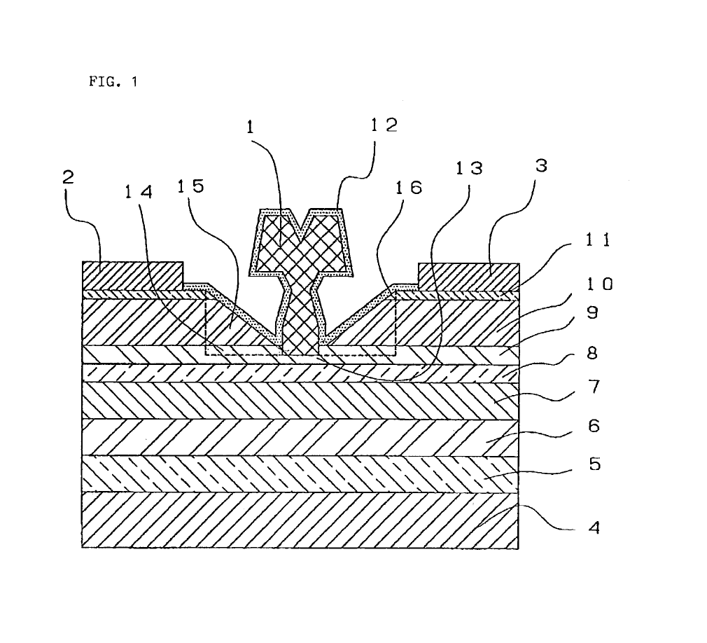

A first embodiment of a heterojunction field-effect transistor (FET) of the present invention will now be described with reference to FIG. 1.

As shown in FIG. 1, the heterojunction FET of the first embodiment comprises a semi-insulating substrate 4, a buffer layer 5, a channel layer 6, a first barrier layer 7, a second barrier layer 8, a lower recess sublayer 9, an upper recess sublayer 10, a contact layer 11, a gate electrode 1, a source electrode 2, and a drain electrode 3, respectively in that order.

The source electrode 2 and the drain electrode 3 are disposed on the upper face of the contact layer 11. The contact layer 11 is a heavily doped n-type GaAs layer, and thus the source electrode 2 and the drain electrode 3 make an ohmic contact with the contact layer 11.

The contact layer 11 and the upper recess sublayer 10 are selectively etched to form a recess. The gate electrode 1 is then formed on the lower recess sublayer 9 and inside the recess. The gate electrode 1 is made of Pt, WSi, or the like. The bottom of the gate electrode 1 is embedded in the lower recess sublayer 9 as a result of vapor deposition, thermal diffusion, sputtering, or the like. The gate electrode 1 and inside and around the recess are covered with a protective film 12. These semiconductor layers are formed by epitaxy such as molecular beam epitaxy (MBE) or metalorganic chemical vapor deposition (MOCVD).

The composition and the configuration of each of the above layers of the heterojunction FET of this embodiment will now be described. The semi-insulating substrate 4 is composed of GaAs or InP. The buffer layer 5 is composed of GaAs. Alternatively, the buffer layer 5 may be composed of AlGaAs, InAlAs, or a combination of GaAs, AlGaAs, and InAlAs, and may have a general superlattice structure. The channel layer 6 is an n-type InGaAs layer. Alternatively, the channel layer 6 may be an n-type doped layer, an undoped layer, a combination thereof, or a GaAs layer. Preferably, the channel layer 6 is doped since a doped layer suppresses carrier transition from the recess layer 9 to the channel layer 6, and thus decreases the series resistance and increases the breakdown voltage. The first barrier layer 7 is composed of AlGaAs. Alternatively, the first barrier layer 7 may be composed of InGaP, InAlAs, or the like. Although the first barrier layer 7 of this embodiment is n-type, it may alternatively be an undoped layer or a combination of an n-type layer and an undoped layer. The second barrier layer 8 is an undoped AlGaAs layer. The lower recess sublayer 9 is an n-type AlGaAs layer having a carrier density of 1.5×10⁺¹⁸ cm⁻³ and a thickness of 10 nm. The upper recess sublayer 10 is an n-type GaAs layer having a carrier density of 7×10⁺¹⁷ cm⁻³ and a thickness of 250 nm. Alternatively, a combination of the lower recess sublayer 9 having a carrier density of 2.0×10⁺¹⁸ cm⁻³ and the upper recess sublayer 10 having a carrier density of 3.0×10⁺¹⁸ cm⁻³ may be employed. The contact layer 11 is a heavily doped n-type GaAs layer which provides an ohmic contact.

As indicated by the dotted lines in FIG. 1, the recess region has a depth from the top edge of the recess to the bottom end of the gate electrode 1 and a width from the top edge of the recess to the opposite top edge of the recess, excluding the section where the gate electrode 1 is formed. The recess region includes a first recess region 14, which is part of the lower recess sublayer 9 composed of n-type AlGaAs having a carrier density of 1.5×10⁺¹⁸ cm⁻³, and a second recess region 15 which is part of the upper recess sublayer 10 composed of n-type GaAs having a carrier density of 7×10⁺¹⁷ cm⁻³. portion of the contact layer 11 inside the recess region, a contact layer 16, is so small that it hardly has any influence on the field concentration inside the recess region. Since the difference in carrier density among layers inside the recess region is small, the field concentration can be moderated, and breakdown due to an applied field can be suppressed.

The bandgap of n-type AlGaAs constituting the lower recess sublayer 9 is larger than that of the n-type GaAs constituting the upper recess sublayer 10. Thus, the difference in bandgap at the junction face between the lower recess sublayer 9 and the upper recess sublayer 10 generates an energy gap that forms a depletion layer. As a result, the applied field is dispersed, and the voltage proof between the gate and the drain (or source) can be increased.

Since the electric field concentrates at a comer 13 of the gate electrode 1, the comer 13 is embedded in the lower recess sublayer 9 composed of n-type AlGaAs having a large band gap and a low impact ionization rate so as to prevent field concentration in the comer 13 of the gate electrode 1 and to increase the breakdown voltage.

Alternatively, the lower recess sublayer 9 may be composed of a material having a large band gap, other than AlGaAs. Examples of the materials for the lower recess sublayer 9 include InGP, InGaAlP, and InGaAlAs. The upper recess sublayer 10 may be formed of other materials having a band gap substantially the same as that of GaAs.

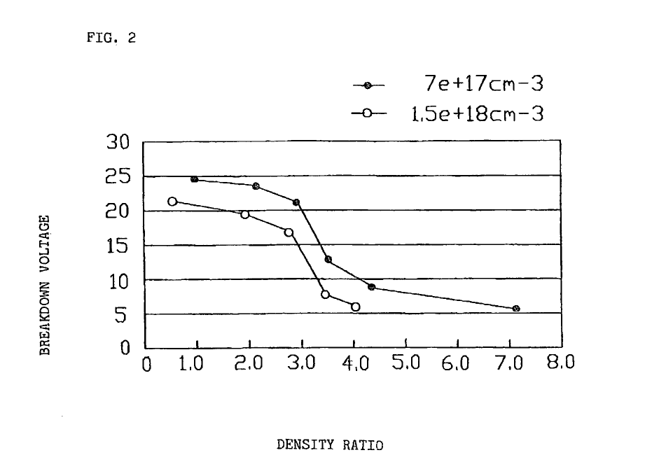

The relationship between the carrier densities of the lower recess sublayer 9 and the upper recess sublayer 10 of the heterojunction FET of this embodiment will now be described with reference to the graph shown in FIG. 2.

FIG. 2 shows the breakdown voltage of the heterojunction FET of this embodiment versus the ratio of the carrier density of the lower recess sublayer 9 to the carrier density of the upper recess sublayer 10 or vice versa (hereinafter the “density ratio”). The curve connecting the black circles represents the relationship between the density ratio (lower recess sublayer 9/upper recess sublayer 10) and the breakdown voltage when the carrier density of the upper recess sublayer 10 is fixed at 7×10⁺¹⁷ cm⁻³ and the carrier density of the lower recess sublayer 9 is varied. The curve connecting the open circles represents the relationship between the density ratio (upper recess sublayer 10/lower recess sublayer 9) and the breakdown voltage when the carrier density of the lower recess sublayer 9 is fixed at 1.5×10⁺¹⁸ cm⁻³ and the carrier density of the upper recess sublayer 10 is varied. The curves in FIG. 2 demonstrate that when the density ratio is between 1.0 and 3.0, the breakdown voltage is maintained at a high level. The breakdown voltage dramatically decreases at a density ratio exceeding 3.0. To obtain the density ratio based on the lower recess sublayer 9, either 1) the density ratio indicated by the curve connecting the white circles (lower recess layer 9/upper recess layer 10) is taken, resulting in a range between 1 and 3, or 2) the reciprocal of the density ratio indicated by the curve connecting the black circles (lower recess sublayer 9/upper recess sublayer 10) is taken. The preferable range is then between 1 and ⅓. Accordingly, in order to maintain the breakdown voltage at a high level, the carrier density of the upper recess sublayer 10 must be ⅓ to 3 times the carrier density of the lower recess sublayer 9.

The preferable range of the carrier density in the recess region is 7×10⁺¹⁷ cm⁻³ to 5×10⁺¹⁸ cm⁻³ so as to regulate the surface depletion layer in the recess region and to achieve a high breakdown voltage. Thus, the carrier densities of the lower recess sublayer 9 and the upper recess sublayer 10 are preferably in the range of 7×10⁺¹⁷ cm⁻³ to 5×10⁺¹⁸ cm⁻³ while the carrier density of the upper recess sublayer 10 must be ⅓ to 3 times the carrier density of the lower recess sublayer 9.

Second Embodiment

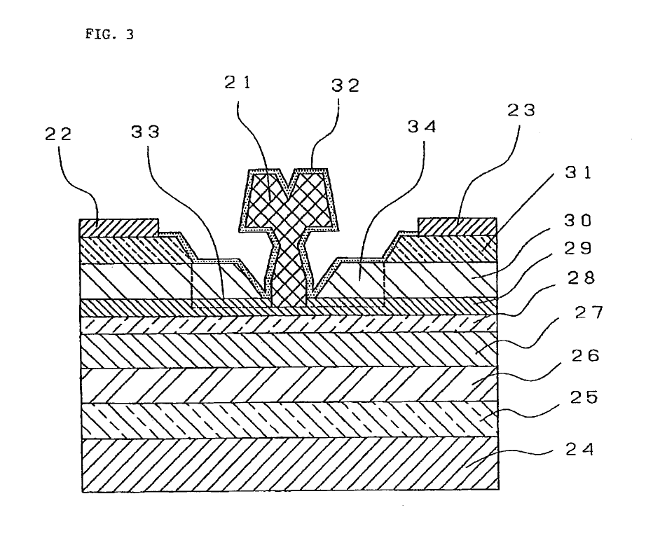

A second embodiment of a heterojunction field-effect transistor (FET) of the present invention will now be described with reference to FIG. 3.

As shown in FIG. 3, the heterojunction FET of this embodiment has a two-step recess structure. The heterojunction FET includes a semi-insulating substrate 24, a buffer layer 25, a channel layer 26, a first barrier layer 27, a second barrier layer 28, a lower recess sublayer 29, an upper recess sublayer 30, a contact layer 31, a gate electrode 21, a source electrode 22, and a drain electrode 23, respectively in that orfer. The semi-insulating substrate 24 is the bottom layer.

The source electrode 22 and the drain electrode 23 are disposed on the upper face of the contact layer 31. The contact layer 31 is a heavily doped n-type GaAs layer, and the source electrode 22 and the drain electrode 23 make an ohmic contact with the contact layer 31.

Referring to FIG. 3, the contact layer 31 is selectively etched to form a large recess and the exposed lower recess sublayer 29 is then selectively etched to form a small recess, thereby providing a multi-step recess between the gate and drain (source). The gate electrode 21 is formed in the recess so that the bottom portion of the gate electrode 21 is embedded in the second barrier layer 28. The process for embedding is the same as in the first embodiment. The gate electrode 21 and inside and around the recess are covered with a protective film 32. These layers are formed by epitaxy such as molecular beam epitaxy (MBE) or metalorganic chemical vapor deposition (MOCVD). Each of the layers of the second embodiment of the heterojunction FET is made of the same material as in the first embodiment.

In the heterojunction FET having a two-step recess structure, the path between the gate electrode 21 and the source electrode 22 and the path between the gate electrode 21 and the drain electrode 23 have a two-step structure. With such a two-step structure, the applied electric field has a stepped characteristic, and the electric field applied to each step can be made smaller than in a single-step recess structure. Thus, the breakdown voltage of the element can be increased compared to the single recess structure of the first embodiment.

As indicated by the dotted lines in FIG. 3, the recess region has a depth from the lower face of the contact layer 31 to the bottom end of the gate electrode 21 and a width from an edge of the contact layer 31 to the opposite edge of the contact layer 31, excluding the section where the gate electrode 21 is formed. The recess region includes a first recess region 33, which is part of the lower recess sublayer 29 composed of n-type AlGaAs having a carrier density of 2×10⁺¹⁸ cm⁻³, and a second recess region 34, which is part of the upper recess sublayer 30 composed of n-type GaAs having a carrier density of 2×10⁺¹⁸ cm⁻³. Since the carrier densities of the layers that constitute the recess region are the same, the field concentration can be further reduced when compared with the first embodiment, and the breakdown due to the applied field can be prevented.

Preferably, the thickness of the lower recess sublayer 29 is in the range of 5 to 10 nm and the thickness of the upper recess sublayer 30 is in the range of 20 to 30 nm. With such thicknesses, depletion can be prevented over the entirety of the recess region.

Although the recess layer of the first and second embodiments disposed between the contact layer and the barrier layer is constituted from two sublayers, the recess layer may include three or more sublayers. Instead of a plurality of barrier layers, only one undoped barrier layer can be employed in the structure described in the first or second embodiment so as to form a doped channel heterojunction field-effect transistor.

While preferred embodiments of the invention have been described above, it is to be understood that variations and modifications will be apparent to those skilled in the art without departing the scope and spirit to the invention. The scope of the invention, therefore, is to be determined solely by the following claims.

What is claimed:

1. A heterojunction field-effect transistor having a gate recess structure, the heterojunction field-effect transistor comprising:
a gate electrode;
a barrier layer;
a contact layer; and
a recess layer formed between the barrier layer and the contact layer, the recess layer comprising a plurality of recess sublayers,
wherein the bottom of the gate electrode is embedded in the lowest sublayer of said plurality of recess sublayers, and
the carrier density of the lowest sublayer is ⅓ to 3 times the carrier density of the other sublayers.

2. The heterojunction field-effect transistor according to claim 1, wherein the carrier density of the lowermost sublayer of said plurality of recess sublayers is substantially the same as that of the other recess sublayers.

3. The heterojunction field-effect transistor according to claim 1 or 2, wherein each of the recess sublayers has a carrier density in the range of 7×10⁺¹⁷ to 5×10⁺¹⁸ cm⁻³.

4. The heterojunction field-effect transistor according to claim 1 or 2, wherein the barrier layer is formed under the lowermost layer of said plurality of recess sublayers, and the barrier layer is an undoped layer.

5. The heterojunction field-effect transistor according to claim 1 or 2, wherein the recess layer has a two-layer structure comprising a lower recess sublayer having a thickness in the range of 5 to 10 nm and an upper recess sublayer having a thickness in the range of 20 to 30 nm.

6. The heterojunction field-effect transistor according to claim 1 or 2, wherein the lowermost sublayer of said plurality of recess sublayers has a band gap larger than that of GaAs.

7. The heterojunction field-effect transistor according to claim 1 or 2, wherein the recess layer comprises an AlGaAs sublayer and a GaAs sublayer.

8. The heterojunction field-effect transistor according to claim 7, wherein the AlGaAg sublayer is the lowermost recess sublayer.

9. The heterojunction field-effect transistor according to claim 1 or 2, wherein the heterojunction field-effect transistor is a doped channel heterojunction field-effect transistor.

10. The heterojunction field-effect transistor according to claim 1 or 2, having a multi-step recess structure.

11. A heterojunction field-effect transistor having a gate recess structure, the heterojunction field-effect transistor comprising:
a gate electrode;
a barrier layer;
a contact layer; and
a recess layer formed between the barrier layer and the contact layer, the recess layer comprising a lower sublayer and an upper sublayer,
wherein the bottom of the gate electrode is embedded in the lower sublayer, and
the carrier density of the lower sublayer is ⅓ to 3 times the carrier density of the upper sublayer.

12. The heterojunction field-effect transistor according to claim 12, wherein the lower sublayer comprises AlGaAs and has a thickness in the range of 5 to 10 nm, and the upper recess sublayer comprises GaAs and has a thickness in the range of 20 to 30 nm.

13. The heterojunction field-effect transistor according to claim 12, wherein the recess structure is a multi-step recess structure.

14. The heterojunction field-effect transistor according to claim 13, further including a doped channel layer.
